(19) United States
(12) Patent Application Publication
(10) Pub. No.: US 2012/0094727 A1
(43) Pub. Date: Apr. 19, 2012

(54) POWER AMPLIFICATION CIRCUIT AND COMMUNICATION APPARATUS

(76) Inventors: Shigeru Morimoto, Osaka (JP); Kenichi Mori, Osaka (JP); Iwao Kojima, Kyoto (JP); Kazuaki Takahashi, Kyoto (JP); Mikihiro Shimada, Osaka (JP)

(21) Appl. No.: 13/148,513

(22) PCT Filed: Oct. 8, 2010
(86) PCT No.: PCT/JP2010/006031

§ 371 Date: Aug. 9, 2011

(30) Foreign Application Priority Data
Dec. 21, 2009 (JP) 2009-289272

(51) Int. Cl. H04B 1/38; H04B 1/04; H03G 3/20

(52) U.S. Cl. 455/571; 330/131; 455/127.1

(57) ABSTRACT

Provided is a power amplification circuit capable of quickly and highly accurately preventing an output power and a current of a power amplifier from fluctuating when an antenna load changes. A power amplifier 11 amplifies a radio frequency signal and obtains an output signal. A regulator 12 amplifies an input voltage by a predetermined gain and supplies an output voltage to the power amplifier 11. A current monitor 13 monitors an input current to the regulator 12 and obtains a monitor current. A first multiplier 14 multiplies the monitor current by the output voltage of the regulator 12 and obtains a monitor power. A memory 16 prestores a predetermined reference current. A second multiplier 15 multiplies the input voltage by the reference current and obtains a reference power. A gain control section 121 in the regulator 12 controls a predetermined gain based on the monitor power and the reference power.

### TECHNICAL FIELD

The present invention relates to a power amplification circuit which is used in a communication apparatus such as a mobile phone, a wireless LAN, and the like; and a communication apparatus. The present invention more particularly relates to a power amplification circuit for suppressing fluctuations of a current and an output power of a power amplifier when an antenna load changes; and a communication apparatus using the power amplification circuit.

### BACKGROUND ART

A communication apparatus such as a mobile phone, a wireless LAN, and the like is required to include a power amplification circuit for preventing an output power and a current of a power amplifier from fluctuating when an antenna load changes.

In a conventional power amplifier (PA), when an antenna load changes for any reason, an output power and a current of the power amplifier fluctuate. FIG. 10 shows an example of an output power Pout and a current Icc when an antenna load changes in a conventional power amplifier. In FIG. 10, horizontal axes indicate phases at respective VSWRs (Voltage Standing Wave Ratio). As shown in FIG. 10, when the VSWR is 3:1, both of the output power Pout and the current Icc fluctuate depending on the phases.

Further, there has been disclosed a conventional power amplification circuit for preventing an output power Pout and a current Icc of a power amplifier from fluctuating when an antenna load changes (see Patent Literature 1, for example). FIG. 11 shows a configuration of a conventional power amplification circuit 50 disclosed by Patent Literature 1. In FIG. 11, the conventional power amplification circuit 50 includes a power amplifier 51 and voltage control circuit 52.

The power amplifier 51 includes first to third amplification stages 511 to 513 and a bias circuit 514. The power amplifier 51 amplifies a radio frequency signal RFin by using the first to the third amplification stages 511 to 513 and obtains an output signal RFout. The bias circuit 514 supplies a bias voltage V_{APC} to the first to the third amplification stages 511 to 513.

The voltage control circuit 52 supplies an output voltage Vcc to the power amplifier 51. The voltage control circuit 52 includes a regulator 521, a current detection circuit 522, an amplifier 523, a delay circuit 524, a coefficient calculator 525, a square root calculator 526, and a multiplier 527. An input voltage V_{RAMP} is inputted to the regulator 521 via the multiplier 527. The regulator 521 amplifies the input voltage V_{RAMP} and supplies the output voltage Vcc to the second to the third amplification stages 512 to 513 via the current detection circuit 522.

The current detection circuit 522 amplifies a detection current I_{PA} by a predetermined gain α. A detection current αI_{PA} is inputted to the coefficient calculator 525. The amplifier 523 amplifies a reference current I_{REF} by a predetermined gain β. A reference current βI_{REF} is assigned a predetermined delay time in the delay circuit 524 and then inputted to the coefficient calculator 525. The delay circuit 524 is a component for compensating delay of the regulator 521. The coefficient calculator 525 obtain a coefficient F by dividing the reference current βI_{REF} by the detection current αI_{PA}. That is, the coefficient F can be represented by using formula 1.

F=βI_{REF}/αI_{PA} (formula 1)

When a load resistance is R_{L}, an output power Pout of the power amplifier 51 can be represented by using formula 2. As shown in formula 2, the output power Pout of the power amplifier 51 is controlled in accordance with a Vcc². The voltage control circuit 52 adjusts the Vcc² in accordance with the coefficient F such that the output power Pout is maintained constant when the load resistance R_{L} changes. That is, the Vcc is adjusted in accordance with √F.

Pout=Vcc²/2·R_{L} (formula 2)

Accordingly, the square root calculator 526 calculates a coefficient √F that is a square root of the coefficient F. The multiplier 527 multiplies an input voltage V_{RMP} by the coefficient √F and outputs the resulting input voltage to the regulator 521.

With the above configuration, the conventional power amplification circuit 50 prevents the output power Pout and the current I_{PA} of the power amplifier 51 from fluctuating when the antenna load changes.

### CITATION LIST

### Patent Literature

[Patent Literature 1] U.S. Pat. No. 7,109,897

### SUMMARY OF THE INVENTION

### Problems to be Solved by the Invention

The antenna load instantaneously changes and thus needs to be controlled quickly; however, in the conventional power amplification circuit 50, the square root calculator 526 calculates the square root of the coefficient F, which may result in delay in a response speed. In addition, there is a problem that a circuit scale is increased by including the square root calculator 526.

Further, because the conventional power amplification circuit 50 controls the output voltage Vcc by using the reference current I_{REF} and the detection current I_{PA} (the input current to the power amplifier 51), the conventional power amplification circuit 50 is required to calculate the reference current I_{REF} which is suitable for the power amplifier 51 having a different individual characteristic. However, in the conventional power amplification circuit 50, the reference current I_{REF} is calculated uniquely based on the input voltage V_{RAMP} correlated with the detection current I_{PA} as a parameter. Accordingly, in the power amplifier 51, the correlation between the input voltage V_{RAMP} and the detection current I_{PA} is variable, and thus the reference current I_{REF} which is suitable is not always applied, resulting in a problem of an erroneous control of the output voltage Vcc.

Therefore, in order to solve the above conventional problems, an objective of the present invention is to provide a power amplification circuit for quickly and highly accurately preventing an output power and a current of a power amplifier from fluctuating when an antenna load changes; and a communication apparatus using the power amplification circuit.

### Solution to the Problems

An objective of the present invention is directed to a power amplification circuit for amplifying a radio frequency signal and obtaining an output signal. In order to achieve the above objective, the power amplification circuit according to the present invention includes: a power amplifier for amplifying the radio frequency signal and obtaining the output signal; a regulator for amplifying an input voltage by a predetermined gain and supplying an output voltage to the power amplifier; a current monitor for monitoring an input current to one of the regulator and the power amplifier and obtaining information of a monitor current; first multiplication means for multiplying the information of the monitor current by information of the output voltage of the regulator and obtaining information of a monitor power; a memory having prestored therein information of a predetermined reference current; and second multiplication means for multiplying information of the input voltage by the information of the reference current and obtaining information of a first reference power. The regulator includes a gain control section for controlling the predetermined gain on the basis of the information of the monitor power and the information of the first reference power.

More specifically, the gain control section controls the predetermined gain such that the information of the first reference power equals the information of the monitor power. Alternatively, the gain control section may use, as information of a second reference power, a product obtained by multiplying the information of the first reference power by a reference gain of the regulator; and control the predetermined gain such that the information of the second reference power equals the information of the monitor power.

Preferably, the regulator includes: a transistor for supplying an output voltage to the power amplifier; a resistance circuit having a first resistance value; a variable resistance circuit having a second resistance value; and an error amplifier for: receiving a feedback of the output voltage of the transistor via the resistance circuit and the variable resistance circuit; comparing the information of the input voltage to the regulator with information of the output voltage of the transistor; and adjusting an input voltage to the transistor. The variable resistance circuit controls the second resistance value such that the information of the first reference power equals the information of the monitor power. Alternatively, the variable resistance circuit may use, as information of a second reference power, a product obtained by multiplying the information of the first reference power by a reference gain of the regulator, and control the second resistance value such that the information of the second reference power equals the information of the monitor power.

The memory may prestore a plurality of pieces of information of the reference current that correspond to an output power of the power amplifier. The second multiplication means: reads, from the memory, the corresponding piece of information of the reference current that corresponds to the output power of the power amplifier; multiplies the information of the input voltage by the corresponding piece of information of the reference current; and obtains the information of the first reference power.

Preferably, the information of the reference current is set to one of a value of information of the input current when there is no load fluctuation and a value greater than the value of the information of the input current. In this case, the gain control section compares the information of the reference current with the information of the input current, and when the information of the input current is less than the information of the reference current, sets the predetermined gain to a reference gain of the regulator. Meanwhile, the gain control section compares the information of the reference current with the information of the input current, and when the information of the input current is greater than or equal to the information of the reference current, controls the predetermined gain such that a product obtained by multiplying the information of the first reference power by a reference gain of the regulator equals the information of the monitor power.

Alternatively, the gain control section compares information of a predetermined threshold current with the information of the input current, and when the information of the input current is greater than or equal to the information of the predetermined threshold current, controls the predetermined gain such that a product obtained by multiplying the information of the first reference power by a reference gain of the regulator equals the information of the monitor power.

The power amplification circuit may further include: a first low-pass filter for band-limiting the input voltage with a predetermined cutoff frequency and outputting the resulting input voltage to the regulator; a second low-pass filter for band-limiting the output voltage of the regulator with a predetermined cutoff frequency and outputting the resulting output voltage to the first multiplication means; and a third low-pass filter for band-limiting the monitor current with a predetermined cutoff frequency and outputting the resulting monitor current to the first multiplication means.

Alternatively, the power amplification circuit may further include a delay circuit for delaying the input voltage for a predetermined time period so as to adjust a delay time between the input voltage and the output voltage.

Further, the present invention is directed to a communication apparatus. The communication apparatus includes a transmitter for amplifying an input signal and obtaining a transmission signal and an antenna for outputting the transmission signal. The transmitter includes any one of the power amplification circuits described above.

The communication apparatus may further include an antenna duplexer and a reception circuit for processing a reception signal received from the antenna. Alternatively, the communication apparatus may further include an antenna switch and a reception circuit for processing the reception signal received from the antenna.

### Advantageous Effects of the Invention

By applying a power amplification circuit according to the present invention, a gain control section controls a gain Gt of a regulator on the basis of information of a monitor power Pt (Icc×Vo) and information of a reference power Pref (Iref×Vin). In other words, by feedbacking an output voltage Vo of the regulator and controlling the gain Gt of the regulator Vo, the power amplification circuit can quickly and highly accurately control the output voltage. Further, a square root detector is not required, thereby preventing delay in a response speed and an increase in a circuit scale.

Further, by storing information of an optimum reference current Iref in a memory, the output voltage Vo can be precisely controlled in accordance with an individual difference and an output power Pout of a power amplifier. Accordingly, the power amplification circuit can quickly and highly accurately prevent the output power Pout and the current of the power amplifier from fluctuating when the antenna load changes.

Further, when information of an input current Icc is less than information of a threshold current Iref, the power amplification circuit sets a resistance value R2 such that the gain Gt of the regulator becomes a reference gain Go. Meanwhile, when the information of the input current Icc is greater than or equal to the information of the threshold current Iref, the power amplification circuit sets the resistance value R2 such that information of an output power Pref·Go of a multiplier equals information of a monitor power Pref, and controls the gain Gt of the regulator. Thus, when the information of the input current Icc is less than the information of the threshold current Iref, the power amplification circuit does not control the gain Gt of the regulator, and thus unwanted influences of the output voltage Vo and the output power Pout on a ramping waveform can be eliminated. Accordingly, the power amplification circuit can quickly and highly accurately prevent the output power Pout and the current of the power amplifier from fluctuating, when the power amplification circuit is applied to a communication method for performing an intermittently operation.

In addition, in order for a plurality of LPFs to average envelope fluctuations of each input signal, the power amplification circuit can quickly and highly accurately prevent the output power Pout and the current of the power amplifier from fluctuating even when being applied to a modulation method in which an envelope of an input signal changes.

### BRIEF DESCRIPTION OF THE DRAWINGS

FIG. 1 is a block diagram showing an example of a configuration of a power amplification circuit 1 according to a first embodiment of the present invention.

FIG. 2 is a block diagram showing an example of a configuration of a regulator 12.

FIG. 3 is a block diagram showing of an example of a configuration of a power amplification circuit 2 according to a second embodiment of the present invention.

FIG. 4 shows examples of waveforms of an input current Icc, an output voltage Vo, and an output power Pout.

FIG. 5 is a figure describing an advantageous effect of the power amplification circuit 2 according to the second embodiment of the present invention.

FIG. 6 is a block diagram showing an example of a configuration a power amplification circuit 3 according to a third embodiment of the present invention.

FIG. 7 is a block diagram showing an example of a configuration of a power amplification circuit 3a according to the third embodiment of the present invention.

FIG. 8A is a block diagram showing an example of a configuration of a power amplification circuit 1b according to the first embodiment of the present invention.

FIG. 8B is a block diagram showing an example of a configuration of a power amplification circuit 2b according to the second embodiment of the present invention.

FIG. 8C is a block diagram showing an example of a configuration of a power amplification circuit 3b according to the third embodiment of the present invention.

FIG. 8D is a block diagram showing an example of a configuration of a power amplification circuit 1c according to the first embodiment of the present invention.

FIG. 8E is a block diagram showing an example of a configuration of a power amplification circuit 2c according to the second embodiment of the present invention.

FIG. 8F is a block diagram showing an example of a configuration of a power amplification circuit 3c according to the third embodiment of the present invention.

FIG. 8G is a block diagram showing an example of a configuration of a power amplification circuit 1d according to the third embodiment of the present invention.

FIG. 8H is a block diagram showing an example of a configuration of the power amplification circuit 2d according to the third embodiment of the present invention.

FIG. 8I is a block diagram showing an example of a configuration of a power amplification circuit 3d according to the third embodiment of the present invention.

FIG. 9A is a block diagram showing an example of a configuration of a communication apparatus 30a according to a fourth embodiment of the present invention.

FIG. 9B is a block diagram showing an example of a configuration of a communication apparatus 30b according to the fourth embodiment of the present invention.

FIG. 9C is a block diagram showing an example of a configuration of a communication apparatus 30c according to the fourth embodiment of the present invention.

FIG. 10 shows an example of an output power Pout and a current Icc when an antenna load changes in a conventional power amplifier.

FIG. 11 is a block diagram showing a configuration of a conventional power amplification circuit 50.

### DESCRIPTION OF EMBODIMENTS

### First Embodiment

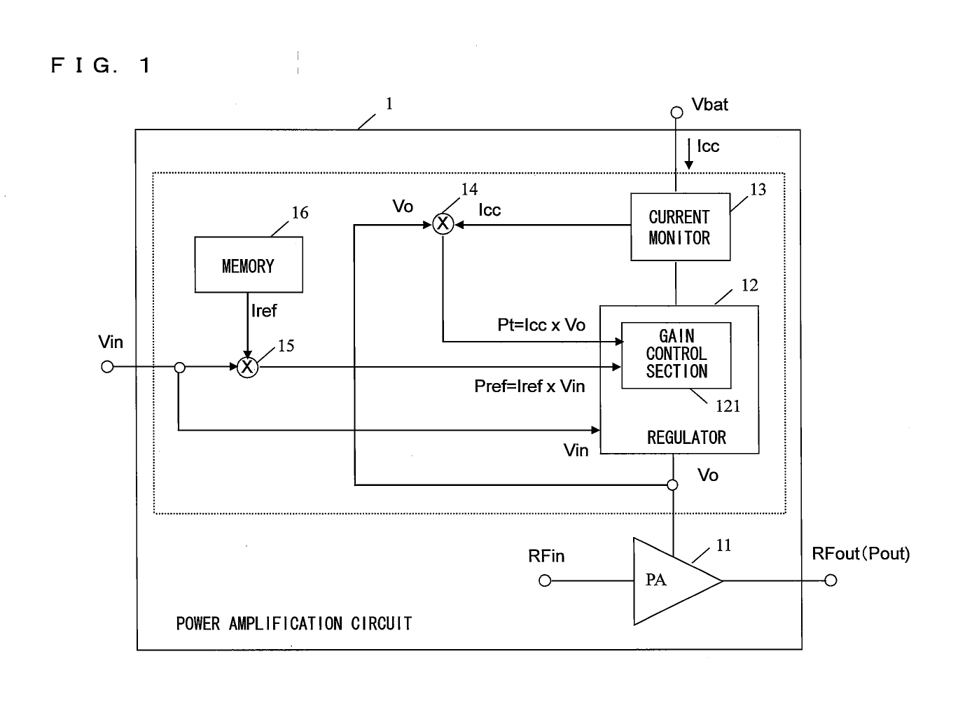

FIG. 1 is a block diagram showing an example of a configuration of a power amplification circuit 1 according to a first embodiment of the present invention. In FIG. 1, the power amplification circuit 1 includes a power amplifier (PA) 11, a regulator 12, a current monitor 13, multipliers 14, 15, and a memory 16. The regulator 12 includes a gain control section 121. The configuration that includes the regulator 12, the current monitor 13, the multipliers 14, 15, and the memory 16 is a configuration for controlling an output voltage Vo and supplying the output voltage Vo to the power amplifier 11, and thus the configuration can be also referred to as a voltage control circuit.

A radio frequency signal RFin which is an input signal is inputted to the power amplifier 11. The power amplifier 11 amplifies the radio frequency signal RFin in accordance with the output voltage Vo from the voltage control circuit and obtains an output signal RFout.

The regulator 12 supplies the output voltage Vo to the power amplifier 11. Specifically, the regulator 12 amplifies an input voltage Vin by a gain Gt controlled by the gain control section 121 and supplies the output voltage Vo to the power amplifier 11. The gain control section 121 controls the gain Gt of the regulator 12. Here, the gain Gt of the regulator 12 can be represented by using formula 3.

Gt=Vo/Vin (formula 3)

The memory 16 prestores information of a predetermined reference current Iref. It is noted that the memory 16 may prestore the information of the reference current Iref that corresponds to an individual difference or the like of the power amplifier 11. Accordingly, the output voltage Vo can be precisely controlled in accordance with the individual difference or the like of the power amplifier 11. Further, the memory 16 may prestore a plurality of pieces of information of the reference current Iref. For example, the memory 16 may prestore a plurality of pieces of information of the reference current Iref that correspond to the output power Pout and to an output frequency of the power amplifier 11. Accordingly, by prestoring the plurality of pieces of the information of the reference current Iref in the memory 16, the output voltage Vo can be precisely controlled in accordance with the output power Pout, the output frequency, and the like of the power amplifier 11.

The multiplier 15 multiplies information of the input voltage Vin by the information of the reference current Iref and outputs information of a reference power Pref. The information of the reference power Pref can be represented by using formula 4.

Pref=Iref×Vin (formula 4)

The current monitor 13 monitors an input current Icc to the regulator 12. It is noted that the current monitor 13 may be connected between the regulator 12 and the power amplifier 11 and monitor an output current of the regulator 12. The multiplier 14 multiples information of the input current Icc monitored by the current monitor 13 by information of the output voltage Vo of the regulator 12 and outputs information of a monitor power Pt. The information of the monitor power Pt can be represented by using formula 5.

Pt=Icc×Vo (formula 5)

In the regulator 12, to the gain control section 121, the reference power Pref is inputted via the multiplier 15 while the monitor power Pt is inputted via the multiplier 14. The gain control section 121 controls the gain Gt of the regulator 12 on the basis of the information of the reference power Pref and the information of the monitor power Pt.

Specifically, the gain control section 121 controls the gain Gt such that a product obtained by multiplying the information of the reference power Pref by the reference gain Go of the regulator 12 equals the information of the monitor power Pt. The reference gain Go is defined by the gain Gt of the regulator 12 when the information of the input current Icc equals the information of the reference current Iref. That is, among the information of the monitor power Pt, the information of the reference power Pref, and the reference gain Go, formula 6 is satisfied.

Pt=Pref×Go (formula 6)

It is noted that when Icc=Iref, Go=Gt.

The gain Gt is controlled for the following reason. When the power amplifier 11 is in a saturational motion, a change in an operation efficiency of the power amplifier 11 is small even when a load changes. Further, the operation efficiency of the power amplifier 11 can be represented by the information of the output power Pout/the information of the input power Icc×Vo (that is, the information of the monitor power Pt represented by formula 5). Accordingly, even when the load changes, information of an input power to the power amplifier 11 is maintained constant at a value Pt, thereby suppressing fluctuations of the output power Pout.

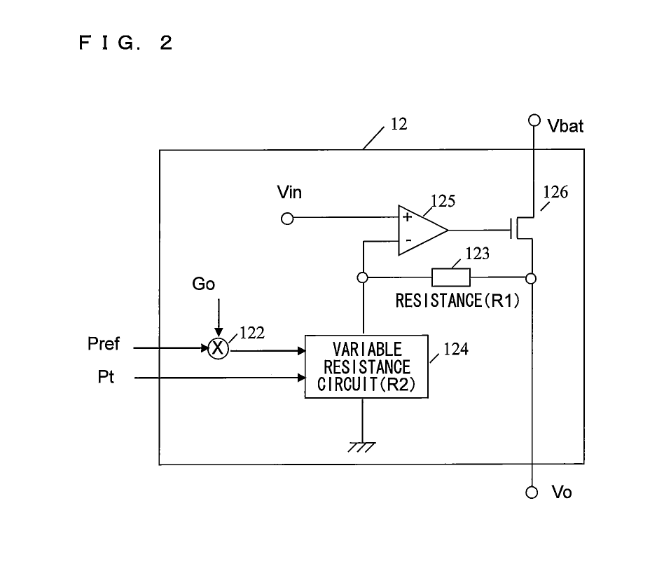

FIG. 2 is a block diagram showing an example of a configuration of the regulator 12. In FIG. 2, the regulator 12 includes a multiplier 122, a resistance 123, a variable resistance circuit 124, an error amplifier 125, and a transistor 126. The regulator 12 amplifies the input voltage Vin by means of the error amplifier 125, the transistor 126, and the resistance 123, and obtains the output voltage Vo. It is noted that the gain control section 121 is composed of the multiplier 122 and the variable resistance circuit 124.

The multiplier 122 multiplies the information of the reference power Pref by the reference gain Go. A resistance value R1 is set in the resistance 123. A resistance value R2 is set in the variable resistance circuit 124. Accordingly, the gain Gt of the regulator 12 is represented by formula 7.

$$\begin{matrix}Gt = Vo / Vin \\ = ( R 1 + R 2 ) / R 2\end{matrix} \qquad ( formula 7 )$$

The variable resistance circuit 124 controls the resistance value R2 such that information of an output power Pref·Go of the multiplier 122 equals the information of the monitor power Pt. In other words, the regulator 12 can control the gain Gt because the variable resistance circuit 124 controls the resistance value R2 so as to be an optimum value.

Accordingly, the voltage control circuit can, by feedbacking the output voltage Vo of the regulator 12 to the regulator 12 and directly controlling the gain Gt of the regulator 12, quickly and highly accurately control the output voltage Vo.

It is noted that the regulator 12 may use a Gm variable circuit as the variable resistance circuit 124.

Further, the multiplier 122 is not necessarily arranged inside the regulator 12, and may be arranged at a stage prior to the regulator 12. In this case, in the regulator 12, to the gain control section 121, the information of the output power Pref·Go is inputted via the multiplier 122 while the information of the monitor power Pt is inputted via the multiplier 14. The gain control section 121 controls the gain Gt such that the information of the output power Pref·Go equals the information of the monitor power Pt.

Further, the power amplification circuit 1 does not necessarily include the multiplier 122. In this case, in the regulator 12, to the gain control section 121, the information of the reference power Pref is inputted via the multiplier 15 while the information of the monitor power Pt is inputted via the multiplier 14. The gain control section 121 controls the gain Gt such that the information of the reference power Pref equals the information of the monitor power Pt. Alternatively, in the power amplification circuit 1, instead of including the multiplier 122, the memory 16 may output a reference current Iref which corresponds to a value obtained by multiplying the reference current Iref by the reference gain Go of the regulator 12. In this case, in the regulator 12, to the gain control section 121, information of a reference power Pref′ is inputted via the multiplier 15 while the information of the monitor power Pt is inputted via the multiplier 14. The gain control section 121 controls the gain Gt such that the information of the reference power Pref′ equals the information of the monitor power Pt.

Further, the power amplification circuit 1 may use, instead of the multiplier 14, any multiplication means for obtaining the information of the monitor power Pt which is obtained by multiplying the information of the input current Icc monitored by the current monitor 13 by the information of the output voltage Vo of the regulator 12. For example, the multiplication means may be for reading information of the optimum monitor power Pt from the memory on the basis of the information of the input current Icc and the information of the output voltage Vo, or may be for obtaining the information of the monitor power Pt by a predetermined calculation.

Further, the power amplification circuit 1 may use, instead of the multiplier 15, any multiplication means for obtaining the information of the reference power Pref which is obtained by multiplying the information of the input voltage Vin by the information of the reference current Iref. For example, the multiplication means may be for reading information of the optimum reference power Pref from the memory on the basis of the information of the input voltage Vin and the information of the reference current Iref, or may be for obtaining the information of the reference power Pref by a predetermined calculation.

Further, the power amplification circuit 1 may use, instead of the multiplier 122, any multiplication means for obtaining the information of the output power Pref·Go which is obtained by multiplying the information of the reference power Pref by the reference gain Go. For example, the multiplication means may be for reading information of the optimum output power Pref·Go from a memory on the basis of the information of the reference power Pref and the reference gain Go, or may be for obtaining the information of the output power Pref·Go by a predetermined calculation.

As described above, in the power amplification circuit 1 according to the first embodiment of the present invention, the gain control section 121 controls the gain Gt of the regulator 12 on the basis of the information of the monitor power Pt (Icc×Vo) and the information of the reference power Pref (Iref×Vin). That is, the power amplification circuit 1 feedbacks the output voltage Vo of the regulator 12 and controls the gain Gt of the regulator 12, thereby enabling quick and highly accurate control of the output voltage Vo. In addition, a square root detector is not required, thereby preventing a delay in a response speed and an increase in a circuit scale.

Further, by storing information of the optimum reference current Iref in the memory 16, the output voltage Vo can be precisely controlled in accordance with the individual difference and the output power Pout of the power amplifier 11. Accordingly, the power amplification circuit 1 can quickly and highly accurately prevent the output power Pout and the current of the power amplifier 11 from fluctuating when the antenna load changes.

### Second Embodiment

A power amplification circuit 2 according to a second embodiment is assumed to be applied, especially to an intermittent operation communication method. Examples of the intermittent operation communication method include a GSM (Global System for Mobile Communications) modulation method.

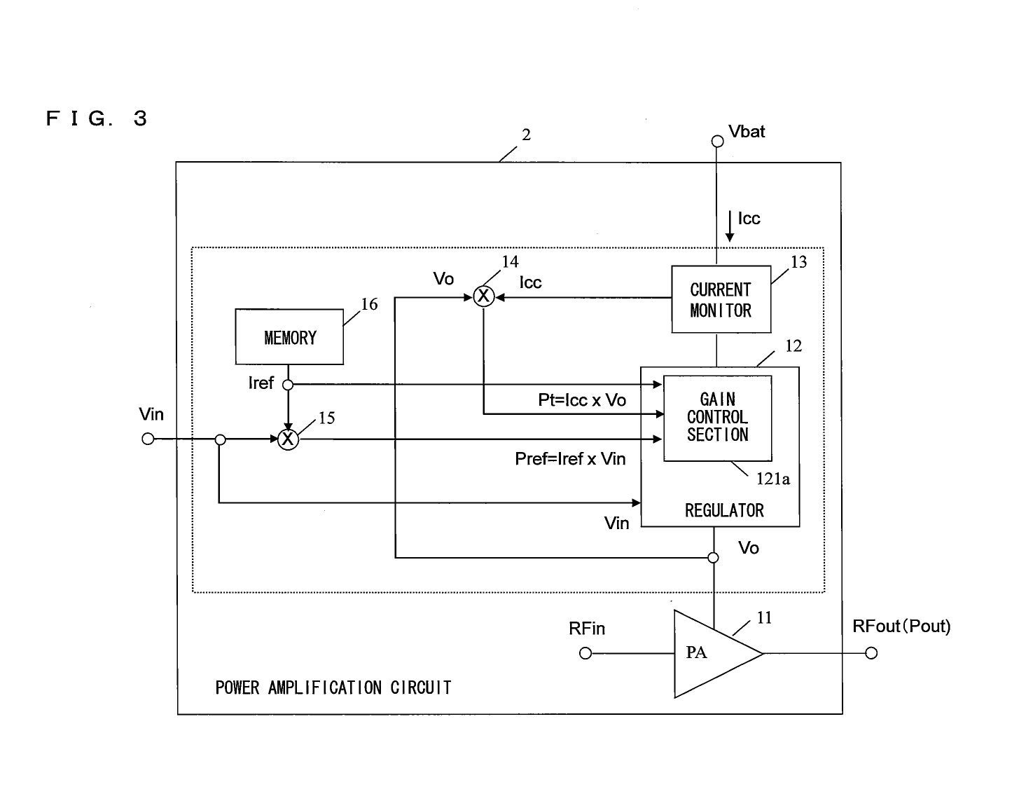

FIG. 3 is a block diagram showing an example of a configuration of the power amplification circuit 2 according to the second embodiment of the present invention. In FIG. 3, the power amplification circuit 2 is different from the power amplification circuit 1 according to the first embodiment in operations of a gain control section 121a. A configuration of the gain control section 121a will be described by utilizing FIG. 2. Further, the information of the reference current Iref stored in the memory 16 is set to the information of the input current Icc when there is no load fluctuation (that is, the VSWR is 1:1), or to be greater than the information of the input current Icc.

As shown in formula 8, the gain control section 121a, by using the information of the reference current Iref as information of a threshold current, compares the information of the threshold current Iref with the information of the input current Icc. On the basis of a result of the comparison, the gain control section 121a changes a control method of the gain Gt of the regulator 12. Specifically, the gain control section 121a sets the resistance value R2 such that the gain Gt of the regulator 12 becomes the reference gain Go, when the information of the input current Icc is less than the information of the threshold current Iref (that is, when there is no load fluctuation or there is slight load fluctuation).

Vo=Go×Vin here, Icc<Iref

Pt=Pref×Go here, Icc>Iref (formula 8)

It is noted that Go=Gt when Icc=Iref.

Meanwhile, when the information of the input current Icc is greater than or equal to the information of the threshold current Iref (that is, load fluctuation increases), the gain control section 121a sets the resistance value R2 such that the information of the output power Pref·Go of the multiplier 122 equals the information of the monitor power Pt and controls the gain Gt of the regulator 12. In other words, when the information of the input current Icc is greater than or equal to the information of the threshold current Iref, the gain control section 121a controls the output voltage Vo in the same manner as in the operation of the first embodiment.

It is noted that the gain control section 121a may operate in the following manner. In the gain control section 121a, information of a predetermined threshold current is set beforehand. The gain control section 121a compares the information of the predetermined threshold current with the information of the input current Icc, and when the information of the input current Icc is less than the information of the predetermined threshold current, the gain control section 121a sets the resistance value R2 such that the gain Gt of the regulator 12 becomes the reference gain Go. Meanwhile, the gain control section 121a compares the information of the predetermined threshold current with the information of the input current Icc, and when the information of the input current Icc is greater than or equal to the information of the predetermined threshold current, the gain control section 121a: sets the resistance value R2 such that the information of the output power Pref·Go of the multiplier 122 equals the information of the monitor power Pt; and controls the gain Gt of the regulator 12.

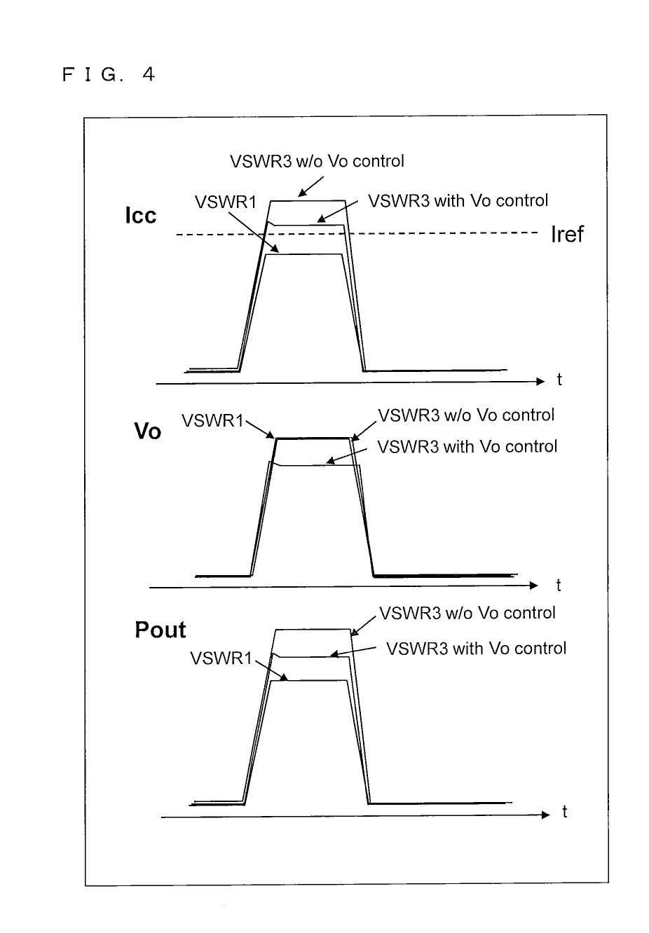

FIG. 4 shows examples of waveforms of the input current Icc, the output voltage Vo, and the output power Pout in the power amplification circuit 2 according to the second embodiment of the present invention. FIG. 4 shows respective waveforms when the VSWR is 1:1, respective waveforms when the VSWR is 3:1 and the output voltage Vo is controlled, and respective waveforms when the VSWR is 3:1 and the output voltage Vo is not controlled (VSWR3 w/o Vo control).

With reference to FIG. 4, in a situation when the VSWR is 3:1, when a case where the output voltage Vo is controlled (VSWR3 with Vo control) is compared with a case where the output voltage Vo is not controlled (VSWR3 w/o Vo control), fluctuations of the input current Icc and the output power Pout due to a change in an antenna load are suppressed. According to the 3GPP (Third Generation Partnership Project), these ramping waveforms are strictly required to have rising and falling forms; however, when the information of the input current Icc is less than the information of the reference current Iref, the gain Gt of the regulator 12 is not controlled, and thus no influence is exerted on the rising and falling forms of the ramping waveforms.

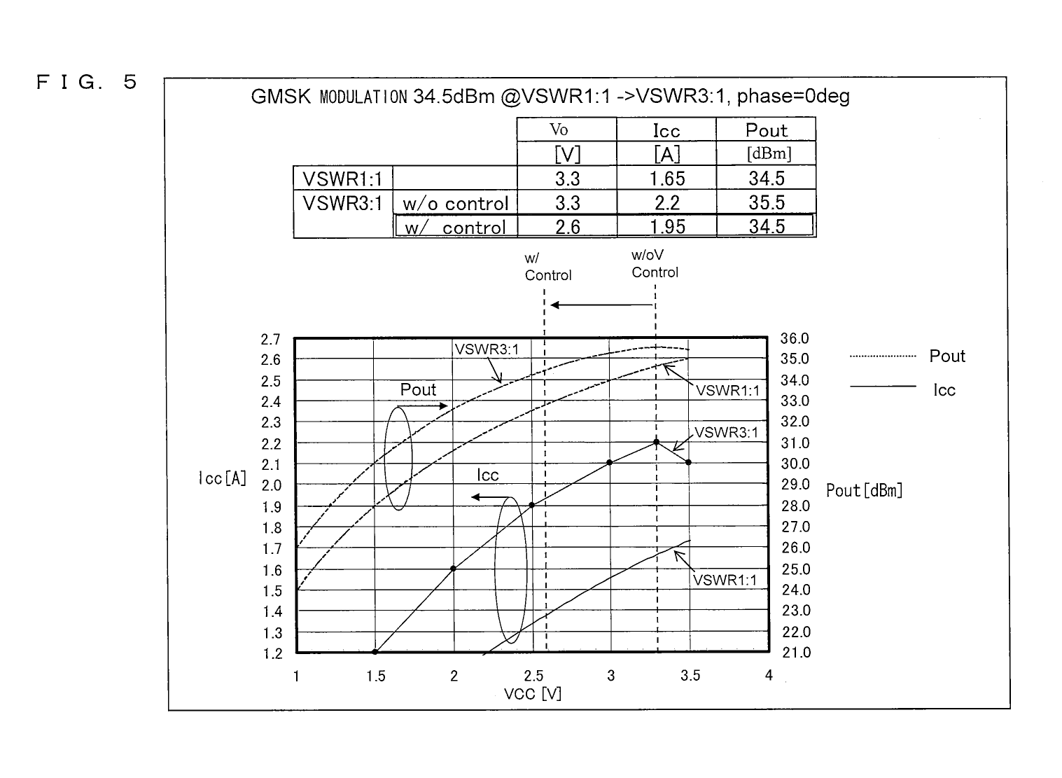

FIG. 5 is a figure describing an advantageous effect of the present invention by showing an example where the power amplification circuit 2 is applied to a GMSK (Gaussian filtered Minimum Shift Keying) modulation method. With reference to FIG. 5, in a situation where the reference current Iref is set to 1.7 A, when the VSWR is 1:1, for example, the output voltage Vo, the input current Icc, and the output power Pout become 3.3 V, 1.65 A, and 34.5 dBm, respectively. On the other hand, when the VSWR is 3:1, if the output voltage Vo is not controlled, the output voltage Vo, the input current Icc, and the output power Pout become 3.3 V, 2.2 A, and 35.5 dBm, respectively, and the input current Icc and output power Pout both increase. In contrast, when the VSWR is 3:1, if the output voltage Vo is controlled, the output voltage Vo, the input current Icc, and the output power Pout become 2.6V, 1.95 A, and 34.5 dBm, respectively, and fluctuations of the input current Icc and the output power Pout can be suppressed.

Especially, there is a case where it is required for the sake of a battery performance or other circuit elements to prevent the input current Icc from greatly fluctuating when the antenna load changes. As shown in FIG. 5, in the power amplification circuit 2, when the VSWR is 3:1 and the output voltage Vo is controlled, the input current Icc becomes 1.95 A, and thus the input current Icc is prevented from increasing. Further, in light of an SAR (specific absorption rate) and the like, there is a case where it is required to prevent the output power Pout from greatly increasing when the antenna load changes. As shown in FIG. 5, in the power amplification circuit 2, when the VSWR is 3:1 and the output voltage Vo is controlled, the output power Pout becomes 34.5 dBm, and thus the output power Pout is prevented from increasing.

As described above, when the information of the input current Icc is less than the information of the threshold current Iref, the power amplification circuit 2 according to the second embodiment of the present invention sets the resistance value R2 such that the gain Gt of the regulator 12 becomes the reference gain Go. Meanwhile, when the information of the input current Icc is greater than or equal to the information of the threshold current Iref, the power amplification circuit 2 sets the resistance value R2 such that the information of the output power Pref·Go of the multiplier 122 equals the information of the monitor power Pt, and controls the gain Gt of the regulator 12. Accordingly, when the information of the input current Icc is less than the information of the threshold current Iref, the gain Gt of the regulator 12 is not controlled, and thus unwanted influences on the ramping waveforms of the output voltage Vo and the output power Pout can be eliminated. Thus, when the power amplification circuit 2 is applied to the intermittent operation communication method, the power amplification circuit 2 can quickly and highly accurately prevent the output power Pout and the current of the power amplifier 11 from fluctuating.

### Third Embodiment

A power amplification circuit 3 according to a third embodiment is assumed to be applied to a modulation method in which envelopes fluctuate. Examples of the modulation method in which the envelopes fluctuate include an EDGE (Enhanced Data GSM Environment) modulation method, a UMTS (Universal mobile telecommunications system) modulation method, and the like.

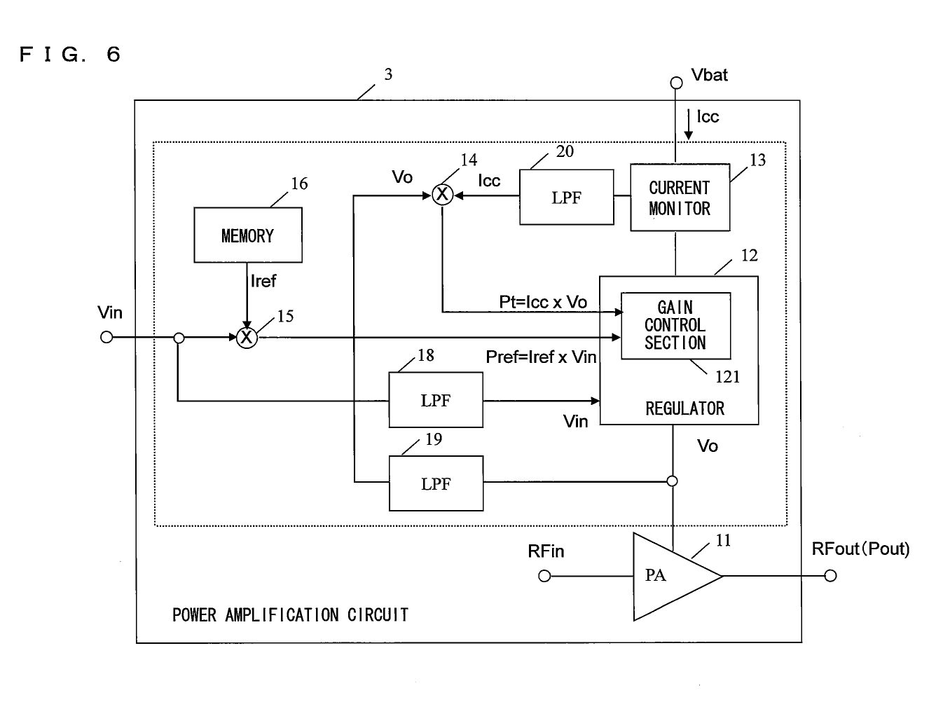

FIG. 6 is a block diagram showing an example of a configuration of the power amplification circuit 3 according to the third embodiment of the present invention. In FIG. 6, the power amplification circuit 3 is different from the power amplification circuit 1 according to the first embodiment in that low-pass filters (LPF) 18, 19, 20 are further included for equalizing envelope fluctuations of each input signal. Basically, an identical cutoff frequency fc is set in each of the LPFs 18, 19, 20. Further, the cutoff frequency fc is set to be an optimum value in accordance with the modulation method to which the present invention is applied.

The LPF 18 band-limits the input voltage Vin with the cutoff frequency fc and outputs the resulting input voltage to the regulator 12. The LPF 19 band-limits the output voltage Vo with the cutoff frequency fc and outputs the resulting output voltage to the multiplier 14. The LPF 20 band-limits the monitor current Icc of the current monitor 13 with the cutoff frequency fc and outputs the resulting monitor current to the multiplier 14.

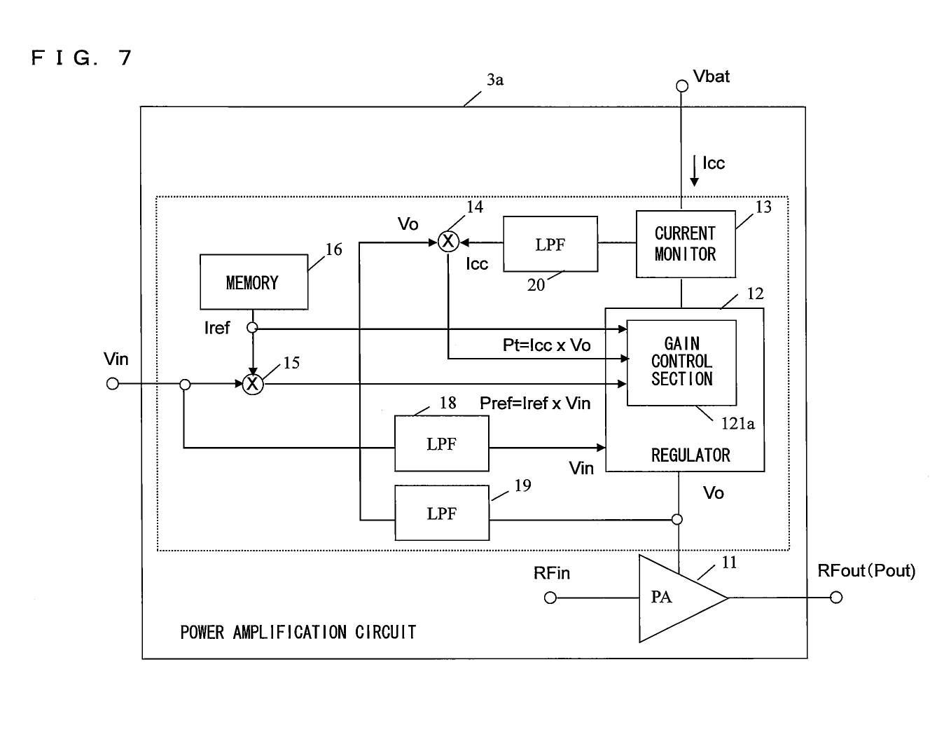

It is noted that the power amplification circuit 3 according to the third embodiment is applicable also to the power amplification circuit 2 according to the second embodiment, as shown in the power amplification circuit 3a of FIG. 7, for example. FIG. 7 is a block diagram showing an example of a configuration of the power amplification circuit 3a according to the third embodiment. In FIG. 7, the power amplification circuit 3a is different from the power amplification circuit 2 according to the second embodiment in that the LPF 18, 19, 20 are further included. The operations of the LPF 18, 19, 20 are as described above.

Accordingly, even when the LPF 18, 19, 20 are applied to the modulation method in which the envelopes fluctuate for equalizing envelope fluctuations of each input signal, the power amplification circuit 3 according to the third embodiment of the present invention can quickly and highly accurately prevent the output power and the current of the power amplifier 11 from fluctuating.

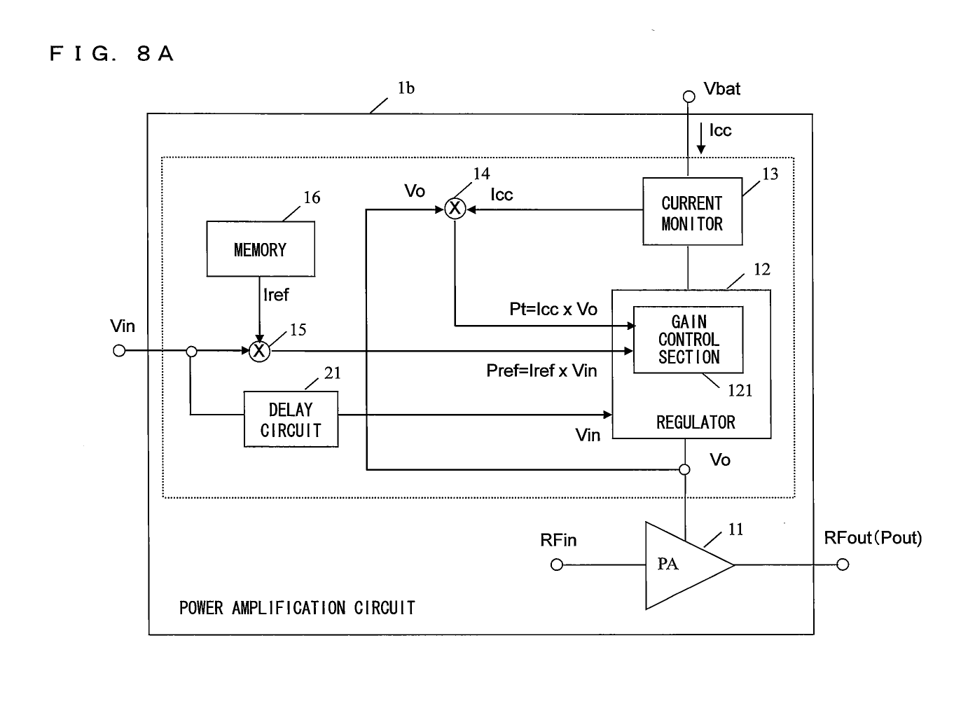

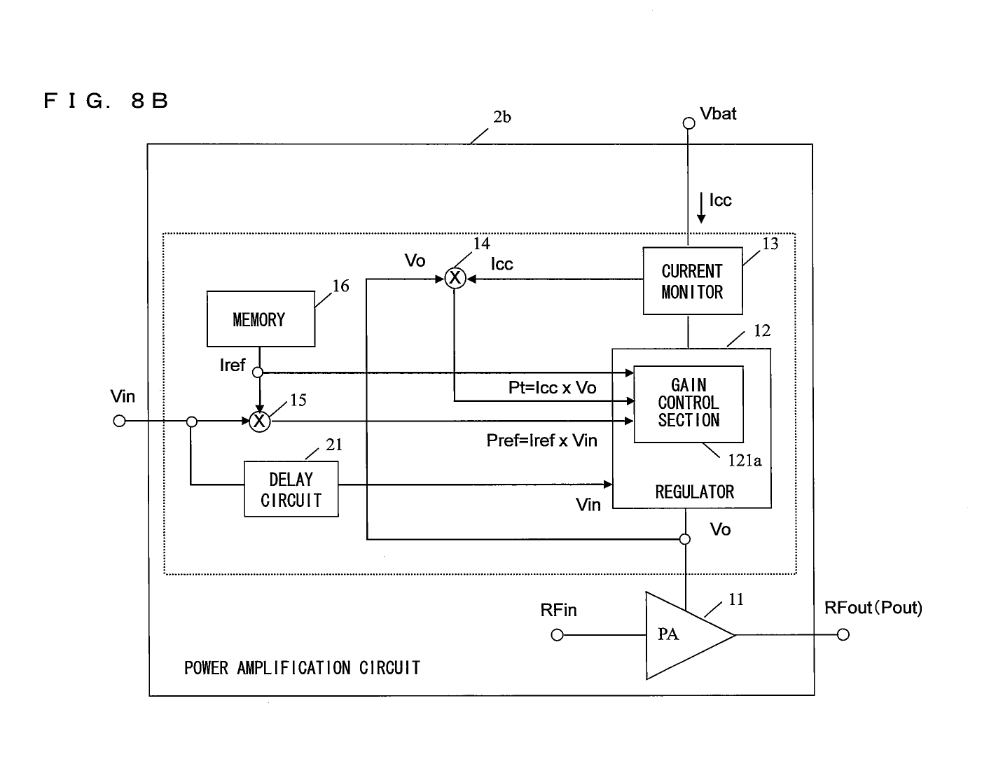

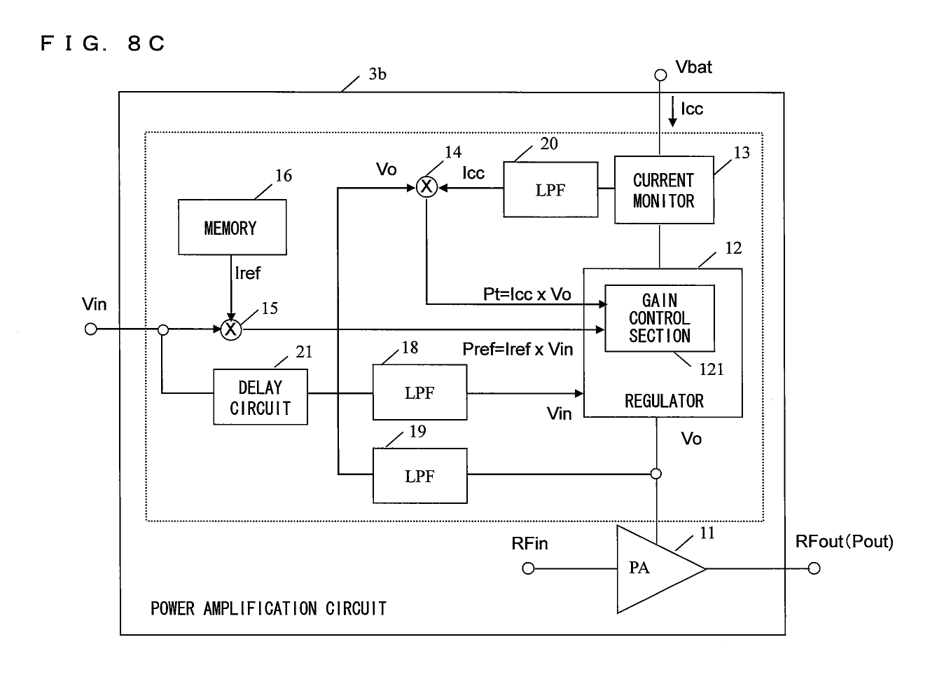

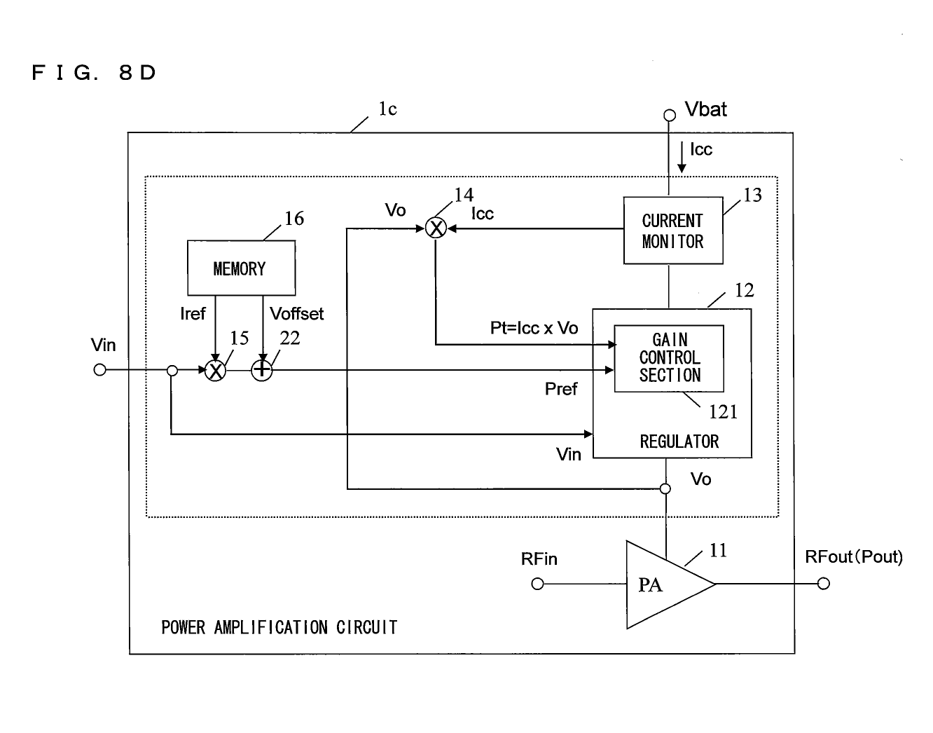

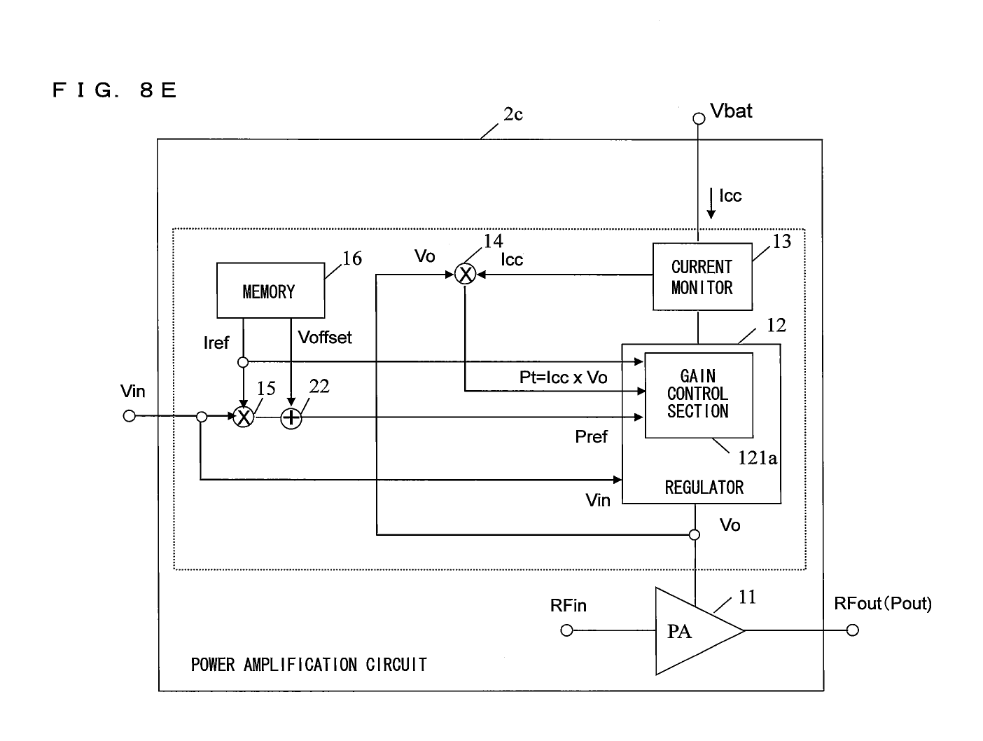

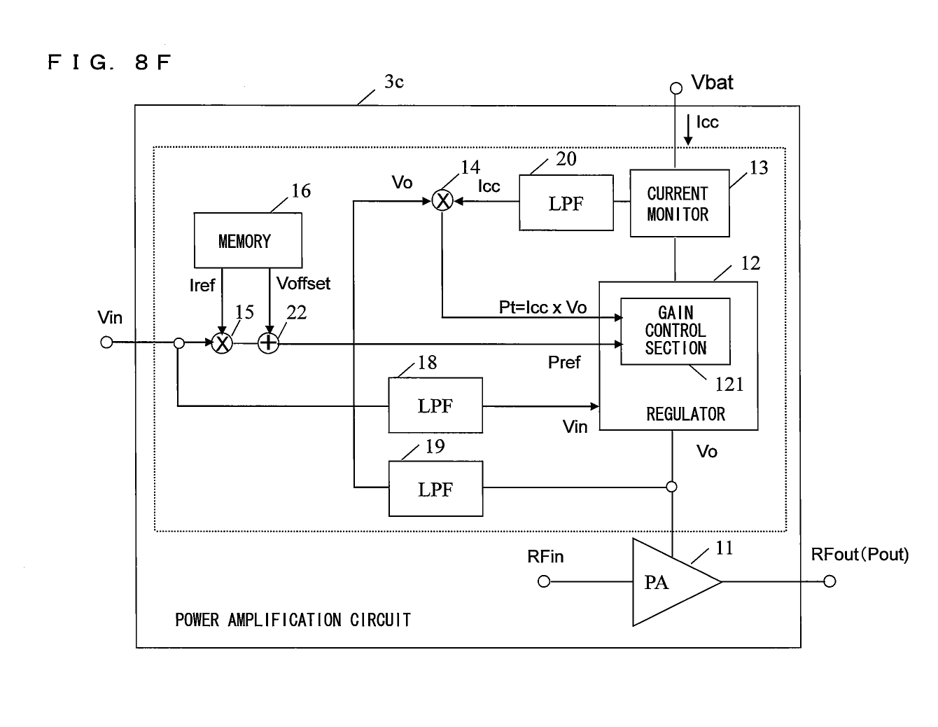

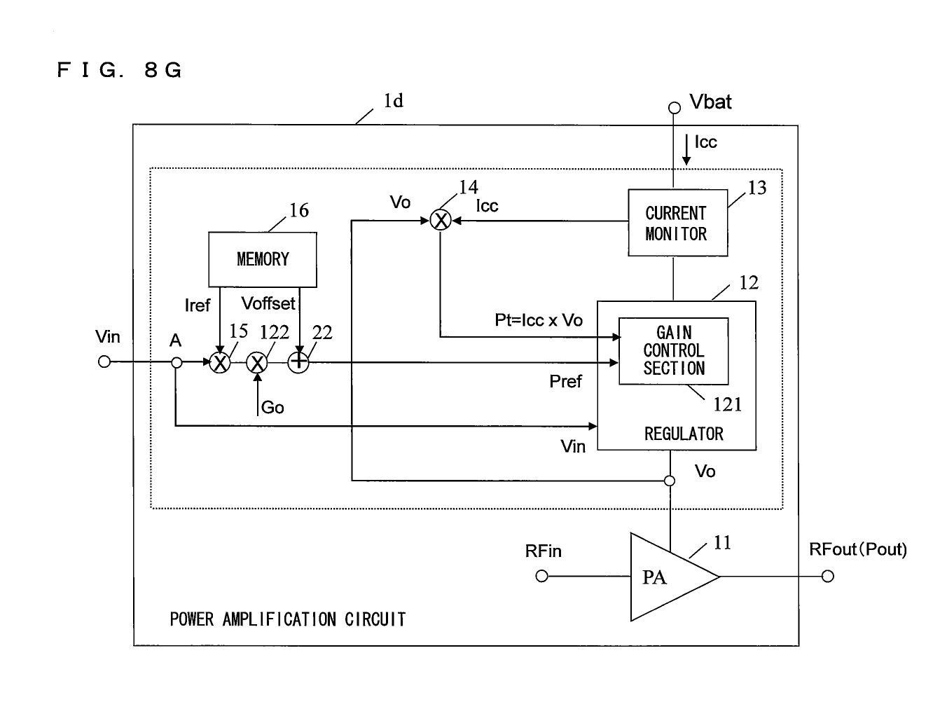

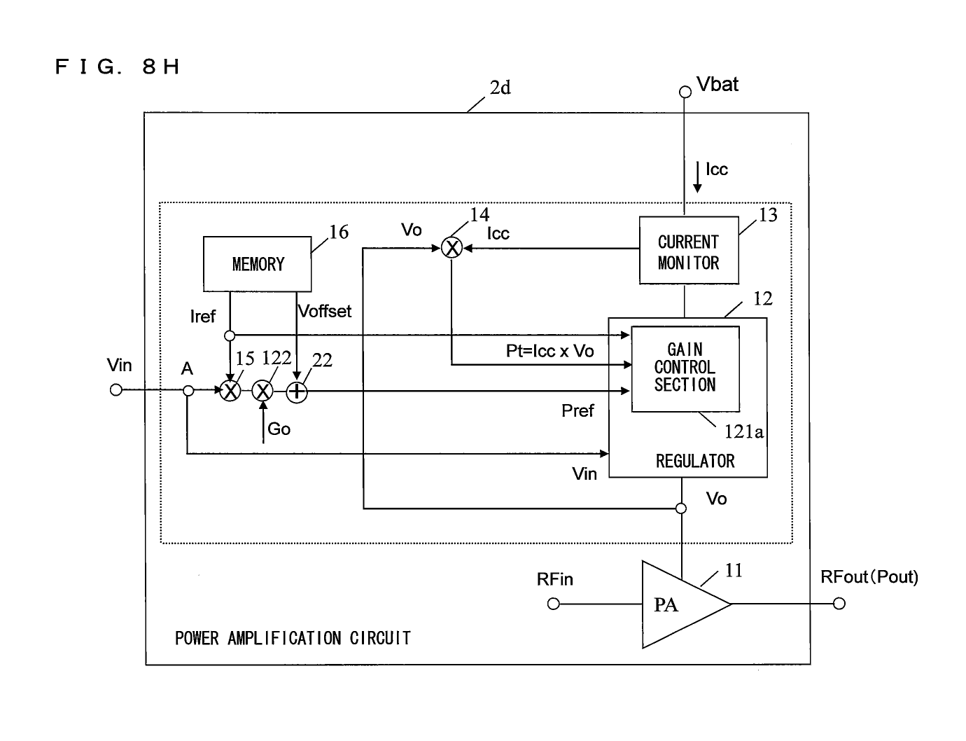

It is noted that the power amplification circuits 1 to 3a according to the first to the third embodiments may further include a delay circuit 21 as in the same manner as the power amplification circuit 1b to 3b shown in FIGS. 8A to C. The delay circuit 21 delays the input voltage Vin for a predetermined time period. Specifically, when a delay is generated in a feedback path of the output voltage Vo of the regulator 12 or the LPFs 18, 19, by delaying the input voltage Vin for the predetermined time period, the delay circuit 21 adjusts respective timings when the input voltage Vin and the feedback output voltage Vo reach the regulator 12. It is noted that the power amplification circuit 3b shown in FIG. 8C may further include a delay circuit on an output side of the LPF 19 or an output side the LPF 20 for adjusting delay of the LPF 19 and the LPF 20.

Further, the power amplification circuits 1 to 3 according to the first to the third embodiments may further include an adder 22 in the same manner as the power amplification circuits 1c to 3c shown in FIGS. 8D to 8F. The adder 22 adds information of an offset voltage Voffset to the reference power Pref. As the information of the offset voltage Voffset, an optimum value may be prestored in the memory 16, or a value may be obtained by a predetermined calculation. In this case, the information of the reference power Pref which is inputted to the gain control section 121 can be represented by using formula 9. The gain control section 121 controls the gain Gt such that the information of the reference power Pref represented by formula 9 equals the information of the monitor power Pt.

Pref=Iref×Vin+Voffset (formula 9)

Further, as in the same manner as the power amplification circuits 1d to 3d shown in FIGS. 8G to I, instead of arranging the multiplier 122 inside the regulator 12, the power amplification circuit 1c may arrange the multiplier 122 between the adder 22 and a branch point A at which the input voltage Vin is branched. The multiplier 122 multiplies the information of the reference power Pref by the reference gain Go. The adder 22 adds the information of the offset voltage Voffset to the information of the output power of the multiplier 122. As the information of the offset voltage Voffset, an optimum value may be prestored in the memory 16, or a value may be obtained by a predetermined calculation. In this case, the information of the reference power Pref which is inputted to the gain control section 121 can be represented by using formula 10. The gain control section 121 controls the gain Gt such that the information of the reference power Pref represented by formula 10 equals the information of the monitor power Pt.

Pref=Iref×Vin×Go+Voffset (formula 10)

### Fourth Embodiment

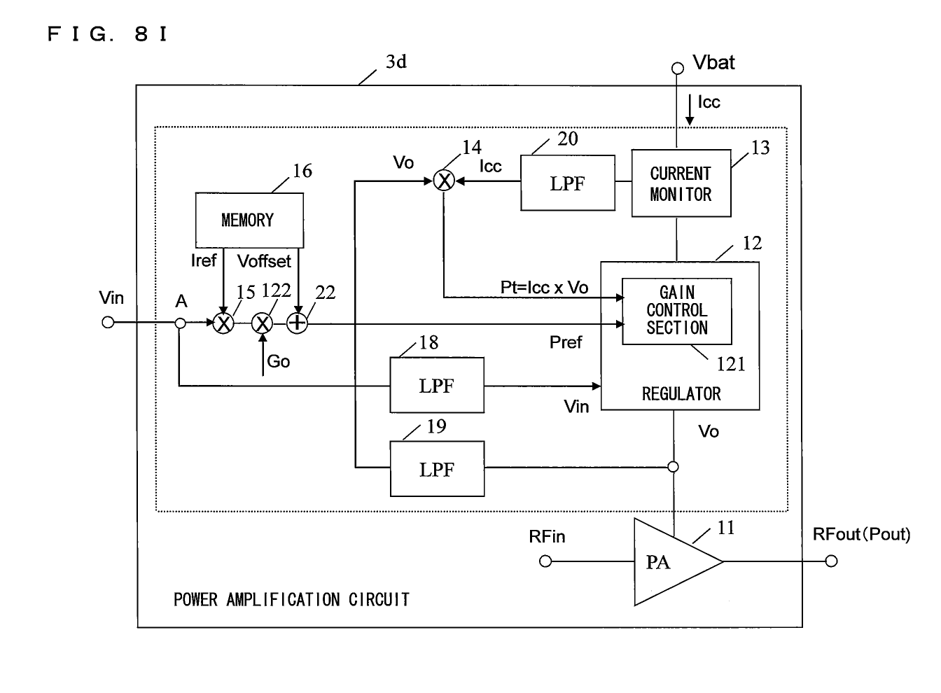

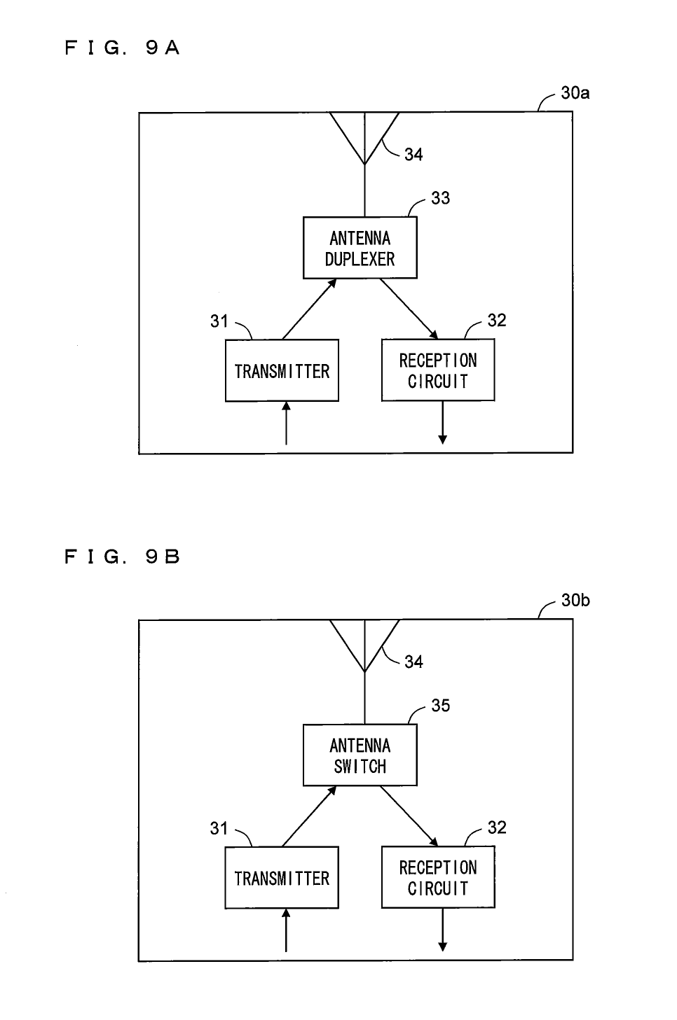

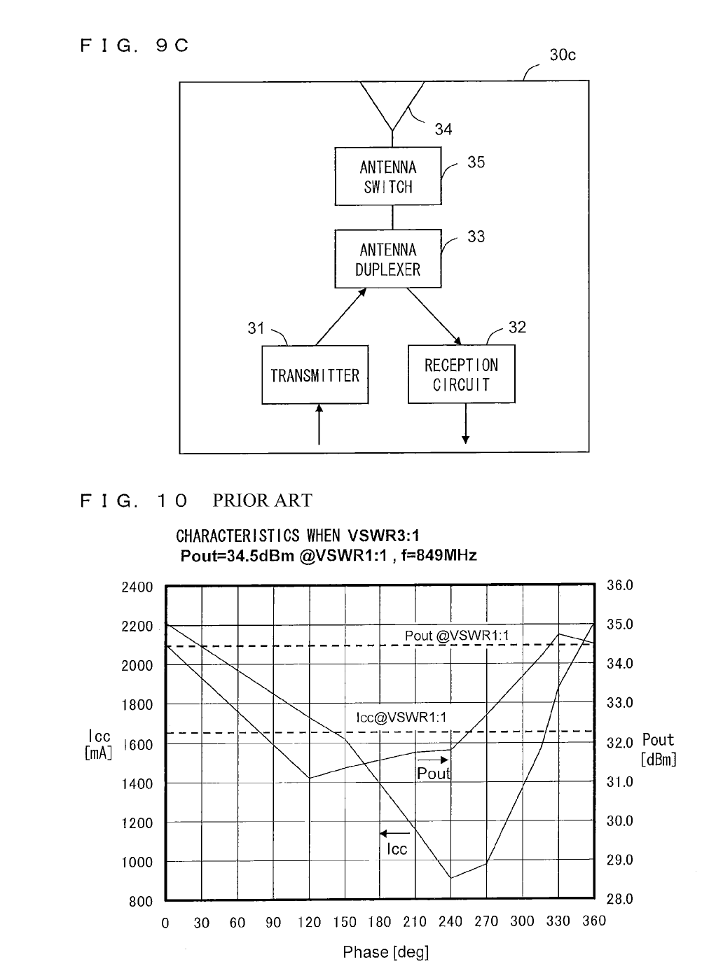

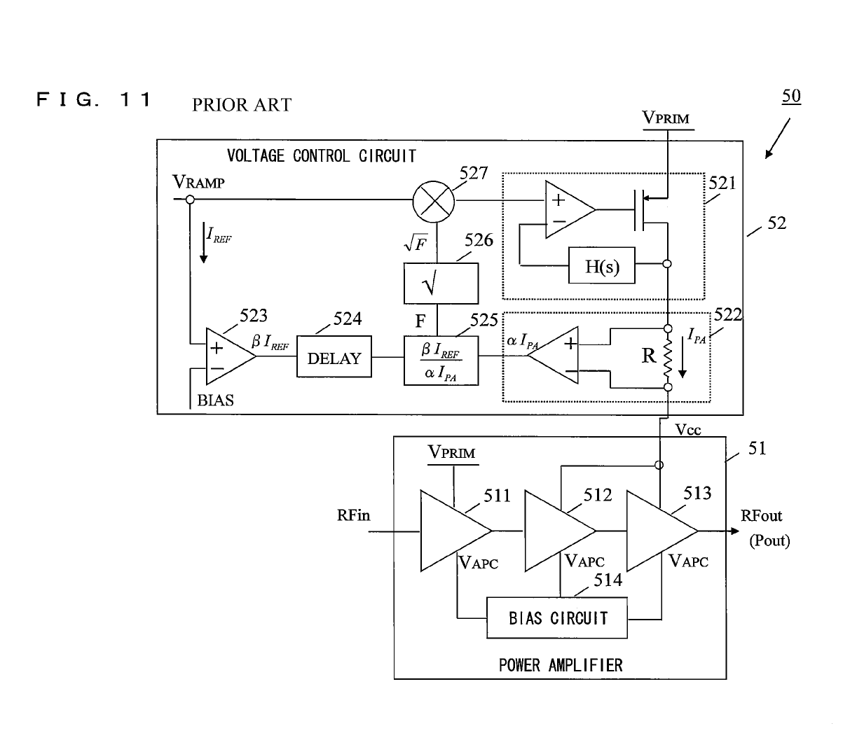

FIG. 9A is a block diagram showing an example of a configuration of a communication apparatus 30a according to a fourth embodiment of the present invention. It is noted that FIG. 9A shows an example where the communication apparatus 30a is applied to the UMTS modulation method. With reference to FIG. 9A, the communication apparatus 30a according to the fourth embodiment includes a transmitter 31, a reception circuit 32, an antenna duplexer 33, and an antenna 34. As the transmitter 31, the power amplification circuit according to one of the first to the third embodiments is used. The transmitter 31 amplifies an input signal and obtains a transmission signal.

The transmission signal from the transmitter 31 is released into open space from the antenna 34 via the antenna duplexer 33. A reception signal is received by the antenna 34, and received by the reception circuit 32 via the antenna duplexer 33. It is noted that the communication apparatus 30a may include only the transmitter 31 and the antenna 34.

FIG. 9B is a block diagram showing an example of a configuration of a communication apparatus 30b according to the fourth embodiment of the present invention. It is noted that FIG. 9B shows an example where the communication apparatus 30b is applied to the GSM modulation method. With reference to FIG. 9B, the communication apparatus 30b according to the fourth embodiment is different from the above described communication apparatus 30a in that an antenna switch 35 is included instead of the antenna duplexer 33. A transmission signal from the transmitter 31 is released into open space from the antenna 34 via the antenna switch 35. A reception signal is receive by the antenna 34 and received by the reception circuit 32 via the antenna switch 35. It is noted that the communication apparatus 30b may include only the transmitter 31 and the antenna 34.

FIG. 9C is a block diagram showing an example of a configuration of a communication apparatus 30c according to the fourth embodiment of the present invention. It is noted that FIG. 9C shows an example where the communication apparatus 30c is applied to a multimode machine in which the UMTS modulation method and the GSM modulation method are provided. With reference to FIG. 9C, the communication apparatus 30c according to the fourth embodiment is different from the above described communication apparatuses 30a, 30b in that both of the antenna duplexer 33 and the antenna switch 35 are included. It is noted that the communication apparatus 30c may include only the transmitter 31 and the antenna 34.

Accordingly, by using the power amplification circuit according to one of the first to the third embodiments, the communication apparatus 30 according to the fourth embodiment can suppress fluctuations of the output power and the current of the transmission circuit 31 even when the antenna load changes.

### INDUSTRIAL APPLICABILITY

The power amplification circuit according to the present invention is applicable to communication apparatuses such as a mobile phone, a wireless LAN, and the like.

### DESCRIPTION OF THE REFERENCE CHARACTERS

1 to 3 power amplification circuit

11 power amplifier (PA)

12 regulator

13 current monitor

14,15 multiplier

16 memory

18 to 20 LPF

21 delay circuit

22 adder

121 gain control section

122 multiplier

123 resistance

124 variable resistance circuit

125 error amplifier

126 transistor

30 communication apparatus

31 transmitter

32 reception circuit

33 antenna duplexer

34 antenna

35 antenna switch

50 power amplification circuit

51 power amplifier

511 to 513 amplification stage

514 bias circuit

52 voltage control circuit

521 regulator

522 current detection circuit

523 amplifier

524 delay circuit

525 coefficient calculator

526 square root calculator

527 multiplier

1. A power amplification circuit for amplifying a radio frequency signal and obtaining an output signal, the power amplification circuit comprising:
a power amplifier for amplifying the radio frequency signal and obtaining the output signal;
a regulator for amplifying an input voltage by a predetermined gain and supplying an output voltage to the power amplifier;
a current monitor for monitoring an input current to one of the regulator and the power amplifier and obtaining information of a monitor current;
first multiplication means for multiplying the information of the monitor current by information of the output voltage of the regulator and obtaining information of a monitor power;
a memory having prestored therein information of a predetermined reference current, and
second multiplication means for multiplying information of the input voltage by the information of the reference current and obtaining information of a first reference power;
wherein
the regulator includes a gain control section for controlling the predetermined gain on the basis of the information of the monitor power and the information of the first reference power.

2. The power amplification circuit according to claim 1, wherein
the gain control section controls the predetermined gain such that the information of the first reference power equals the information of the monitor power.

3. The power amplification circuit according to claim 1, wherein
the gain control section uses, as information of a second reference power, a product obtained by multiplying the information of the first reference power by a reference gain of the regulator; and controls the predetermined gain such that the information of the second reference power equals the information of the monitor power.

4. The power amplifier according to claim 1, wherein
the regulator includes:
a transistor for supplying an output voltage to the power amplifier;
a resistance circuit having a first resistance value;
a variable resistance circuit having a second resistance value; and
an error amplifier for: receiving a feedback of the output voltage of the transistor via the resistance circuit and the variable resistance circuit; comparing information of the input voltage of the regulator with information of the output voltage of the transistor; and adjusting an input voltage of the transistor, and
the variable resistance circuit controls the second resistance value such that the information of the first reference power equals the information of the monitor power.

5. The power amplifier according to claim 1, wherein
the regulator includes:
a transistor for supplying an output voltage to the power amplifier;
a resistance circuit having a first resistance value;
a variable resistance circuit having a second resistance value;
an error amplifier for: receiving a feedback of the output voltage of the transistor via the resistance circuit and the variable resistance circuit; comparing the information of the input voltage to the regulator with information of the output voltage of the transistor; and
adjusting an input voltage to the transistor, and
the variable resistance circuit uses, as information of a second reference power, a product obtained by multiplying the information of the first reference power by a reference gain of the regulator, and controls the second resistance value such that the information of the second reference power equals the information of the monitor power.

6. The power amplification circuit according to claim 1, wherein
the memory prestores a plurality of pieces of information of the reference current that correspond to an output power of the power amplifier, and
the second multiplication means: reads, from the memory, the corresponding piece of information of the reference current that corresponds to the output power of the power amplifier; multiplies the information of the input voltage by the corresponding piece of information of the reference current; and obtains the information of the first reference power.

7. The power amplification circuit according to claim 1, wherein
the information of the reference current is set to one of a value of information of the input current when there is no load fluctuation and a value greater than the value of the information of the input current, and
the gain control section compares the information of the reference current with the information of the input current, and when the information of the input current is less than the information of the reference current, sets the predetermined gain to a reference gain of the regulator.

8. The power amplification circuit according to claim 1, wherein
the information of the reference current is set to one of a value of information of the input current when there is no load fluctuation and a value greater than the value of the information of the input current, and
the gain control section compares the information of the reference current with the information of the input current, and when the information of the input current is greater than or equal to the information of the reference current, controls the predetermined gain such that a product obtained by multiplying the information of the first reference power by a reference gain of the regulator equals the information of the monitor power.

9. The power amplification circuit according to claim 1, wherein
the gain control section compares information of a predetermined threshold current with the information of the input current, and when the information of the input current is greater than or equal to the information of the predetermined threshold current, controls the predetermined gain such that a product obtained by multiplying the information of the first reference power by a reference gain of the regulator equals the information of the monitor power.

10. The power amplification circuit according to claim 1, further comprising:
a first low-pass filter for band-limiting the input voltage with a predetermined cutoff frequency and outputting the resulting input voltage to the regulator;
a second low-pass filter for band-limiting the output voltage of the regulator with a predetermined cutoff frequency and outputting the resulting output voltage to the first multiplication means; and
a third low-pass filter for band-limiting the monitor current with a predetermined cutoff frequency and outputting the resulting monitor current to the first multiplication means.

11. The power amplification circuit according to claim 1, further comprising a delay circuit for delaying the input voltage for a predetermined time period so as to adjust a delay time between the input voltage and the output voltage.

12. A communication apparatus comprising:
a transmitter for amplifying an input signal and obtaining a transmission signal; and
an antenna for outputting the transmission signal, wherein
the transmitter includes the power amplification circuit according to claim 1.

13. The communication apparatus according to claim 12, further comprising:
a reception circuit for processing a reception signal received from the antenna; and
an antenna duplexer.

14. The communication apparatus according to claim 12, further comprising:
a reception circuit for processing a reception signal received from the; and
antenna an antenna switch.
